(19) United States
(12) Patent Application Publication
(10) Pub. No.: US 2024/0345165 A1
(43) Pub. Date: Oct. 17, 2024

(54) FAULT DETECTION METHOD AND FAULT SYMPTOM DIAGNOSIS SYSTEM AND METHOD FOR SOLENOID ACTUATORS

(71) Applicant: HL MANDO CORPORATION, Pyeongtaek-si (KR)

(72) Inventor: Taeyoung KO, Seongnam-si (KR)

(73) Assignee: HL MANDO CORPORATION, Pyeongtaek-si (KR)

(21) Appl. No.: 18/380,003

(22) Filed: Oct. 13, 2023

(30) Foreign Application Priority Data
Apr. 11, 2023 (KR) 10-2023-0047218

(51) Int. Cl. G01R 31/34; G01R 31/52; G01R 31/54; H01F 7/18

(52) U.S. Cl. CPC G01R 31/34; G01R 31/52; G01R 31/54; H01F 7/1844

(57) ABSTRACT

A method of detecting a short or open fault even in a state where a solenoid actuator is not driven, and a system and a method of diagnosing a fault symptom are provided. A fault detection method for a solenoid actuator in a drive circuit of the solenoid actuator including a main controller, a high-side driver, a low-side driver and a short monitoring unit includes: detecting, by the main controller, a first short monitoring measurement value of the short monitoring unit in a state where at least one of the high-side driver and the low-side driver is turned off; comparing, by the main controller, the first short monitoring measurement value with a pre-stored short monitoring threshold value; and determining, by the main controller, a fault of the solenoid actuator based on the comparison result.

### CROSS-REFERENCE TO RELATED APPLICATION

This application claims priority under 35 U.S.C. § 119 to Korean Patent Application No. 10-2023-0047218, filed on Apr. 11, 2023, in the Korean Intellectual Property Office (KIPO), the disclosure of which is incorporated by reference herein in its entirety.

### 1. TECHNICAL FIELD

The present disclosure relates to a fault detection method and a fault symptom diagnosis system and method for a solenoid actuator, and more particularly, a method for detecting a short or open fault even when the solenoid actuator is not driven, and a system and a method for diagnosing fault symptoms.

### 2. DISCUSSION OF RELATED ART

In general, an electronic control unit (ECU) of a vehicle receives signals from various sensors provided in an engine, a transmission (e.g., a gearbox), a brake, a suspension, and the like, transmits a state to a driver, receives an operation command from the driver, and controls the engine, the transmission, the brake, the suspension, and the like. A solenoid is applied as an actuator for driving operation elements of such vehicle equipment, and a variable force solenoid accompanied by current control is applied to obtain more precise control in drive the operation elements. In general, a solenoid actuator may include a coil and an internal resistance, and a drive amount may be adjusted by controlling an amount of current flowing through the coil.

Such an electronic control unit (ECU) of a vehicle needs to diagnose and take action against open and short faults of the solenoid actuator, and in particular, it is necessary to diagnose the fault of the solenoid actuator even when the solenoid actuator is not driven.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

Embodiments of the present disclosure may be directed to a fault detection method for a solenoid actuator capable of detecting a short and open fault of a solenoid actuator even when driving of the solenoid actuator is stopped.

Embodiments of the present disclosure may be also directed to a fault detection method for a solenoid actuator capable of detecting a fault of a solenoid actuator both while the solenoid actuator is driven or stopped driving without changing hardware components of the solenoid actuator.

Embodiments of the present disclosure may be also directed to a fault symptom diagnosis system and method for diagnosing fault symptoms of a solenoid actuator by collecting measurement data for diagnosing a fault of the solenoid actuator and learning the collected data using an artificial neural network.

According to an embodiment, a fault detection method for a solenoid actuator in a drive circuit of the solenoid actuator including a main controller, a high-side driver, a low-side driver and a short monitoring unit includes: detecting, by the main controller, a first short monitoring measurement value of the short monitoring unit in a state where at least one of the high-side driver and the low-side driver is turned off; comparing, by the main controller, the first short monitoring measurement value with a pre-stored short monitoring threshold value; and determining, by the main controller, a fault of the solenoid actuator based on the comparison result.

In some embodiments, the determining, by the main controller, a fault of the solenoid actuator based on the comparison result may include determining that there is a short fault between the solenoid actuator and a B+ line when the first short monitoring measurement value is higher than the short monitoring threshold value in a state where both the high-side driver and the low-side driver are turned off.

In some embodiments, the method may further include preventing, by the main controller, the solenoid actuator from being driven when it is determined that there is a short fault between the solenoid actuator and the B+ line.

In some embodiments, the method may further include detecting, by the main controller, a second short monitoring measurement value of the short monitoring unit and a second HSD current measurement value of the high-side driver in a state where the high-side driver is turned on and the low-side driver is turned off; comparing, by the main controller, the second short monitoring measurement value with a pre-stored short monitoring threshold value and comparing, by the main controller, the second HSD current measurement value with a pre-stored HSD current threshold value; and determining, by the main controller, a fault of the solenoid actuator based on the comparison result.

In some embodiments, the determining, by the main controller, a fault of the solenoid actuator based on the comparison result may include determining that there is a short fault between the solenoid actuator and a ground (GND) when the second HSD current measurement value is higher than the HSD current threshold value and the short monitoring measurement value is lower than the short monitoring threshold value.

In some embodiments, the determining, by the main controller, a fault of the solenoid actuator based on the comparison result may include determining that there is an open fault of the solenoid actuator when the second HSD current measurement value is not higher than the HSD current threshold value and the short monitoring measurement value is not higher than the short monitoring threshold value.

In some embodiments, the determining, by the main controller, a fault of the solenoid actuator based on the comparison result may include determining that the solenoid actuator is normal when the second HSD current measurement value is not higher than the HSD current threshold value and the short monitoring measurement value is higher than the short monitoring threshold value.

In some embodiments, the method may further include executing, by the main controller, a driving solenoid actuator fault detection logic in a state where both the high-side driver and the low-side driver are turned on.

According to an embodiment, a fault symptom diagnosis system for a solenoid actuator includes: a data collector configured to collect data including a fault detection measurement value for each of a plurality of diagnosis dates, a fault date, and a fault type; a data processor configured to calculate a remaining service life for each diagnosis date based on the collected data and generate learning data including the fault detection measurement value, the remaining service life, and the fault type; and an artificial neural network configured to learn to predict a fault type class and a remaining service life based on the fault detection measurement value of the learning data, wherein a fault symptom of the solenoid actuator is diagnosed using the artificial neural network.

In some embodiments, the fault detection measurement value may include a short monitoring measurement value, an HSD current measurement value, and a current detection value.

In some embodiments, the fault detection measurement value may further include at least one of a B+ voltage, a PWM control signal, and a target current value.

In some embodiments, the fault type may include a short fault between the solenoid actuator and a B+ line, a short fault between the solenoid actuator and a ground (GND), and an open fault of the solenoid actuator.

In some embodiments, the artificial neural network may set a difference between a predicted remaining service life and an actual remaining service life as a remaining service life loss function and learn such that that the remaining service life loss function converges to 0.

In some embodiments, the artificial neural network may set a difference between a predicted fault type class and an actual fault type class as a fault type loss function and learn such that that the fault type loss function converges to 0.

According to an embodiment, a fault symptom diagnosis method for a solenoid actuator includes: collecting, by a fault symptom diagnosis system, data including a fault detection measurement value for each of a plurality of diagnosis dates, a fault date, and a fault type; calculating, by the fault symptom diagnosis system, a remaining service life for each diagnosis date based on the collected data and generating learning data including the fault detection measurement value, the remaining service life, and the fault type; learning by an artificial neural network such that the fault symptom diagnosis system predicts a fault type class and a remaining service life based on the fault detection measurement value of the learning data; and diagnosing a fault symptom of the solenoid actuator using the learned artificial neural network.

In some embodiments, the fault detection measurement value may include a short monitoring measurement value, an HSD current measurement value, and a current detection value.

In some embodiments, the fault detection measurement value may further include at least one of a B+ voltage, a PWM control signal, and a target current value.

In some embodiments, the fault type may include a short fault between the solenoid actuator and a B+ line, a short fault between the solenoid actuator and a ground (GND), and an open fault of the solenoid actuator.

In some embodiments, the artificial neural network may set a difference between a predicted remaining service life and an actual remaining service life as a remaining service life loss function and learn such that that the remaining service life loss function converges to 0.

In some embodiments, the artificial neural network may set a difference between a predicted fault type class and an actual fault type class as a fault type loss function and learn such that that the fault type loss function converges to 0.

According to the present disclosure, since a short and open fault of a solenoid actuator may be detected even while driving of the solenoid actuator is stopped, the driving of the solenoid actuator that is out of order may be blocked in advance to prevent damage to a solenoid actuator drive system.

According to the present disclosure, a fault of a solenoid actuator may be detected both while the solenoid actuator is driven or not driven by modifying only software without changing hardware components of the solenoid actuator, such that the solenoid actuator may be driven more safely without increasing the cost.

According to the present disclosure, fault symptoms of a solenoid actuator may be diagnosed in advance and safety measures may be taken before a fault of the solenoid actuator occurs by collecting measurement data for diagnosing a fault of the solenoid actuator and learning the collected data using an artificial neural network.

The effects of the present disclosure are not limited to the effects described above, and other effects not mentioned are clear to a person having ordinary skill in the art (PHOSITA) based on the description of the claims.

### BRIEF DESCRIPTION OF THE DRAWINGS

A more complete appreciation of the present disclosure will become more apparent by describing in detail exemplary embodiments thereof with reference to the accompanying drawings, wherein:

FIG. 1 is a drive circuit diagram of a general solenoid actuator.

FIG. 2 is a flowchart illustrating a fault detection method for a solenoid actuator according to the present disclosure.

FIG. 3 is a configuration diagram illustrating a fault symptom diagnosis system for a solenoid actuator according to the present disclosure.

FIG. 4 is a flowchart illustrating a fault symptom diagnosis method for a solenoid actuator according to an embodiment of the present disclosure.

### DETAILED DESCRIPTION

Hereinafter, embodiments of the present disclosure will be described in detail so that those skilled in the art may easily practice the present disclosure with reference to the accompanying drawings. Since the present disclosure may make various changes and have various embodiments, specific embodiments will be illustrated in the drawings and described in detail in the detailed description. However, this is not intended to limit the present disclosure to specific embodiments, and should be understood to include all modifications, equivalents, or substitutes included in the spirit and technical scope of the present disclosure.

In order to clearly describe the present disclosure, parts irrelevant to the description in the drawings are omitted, and similar reference numerals are assigned to similar parts throughout the specification. In addition, while explaining with reference to the drawings, even if the configuration is indicated by the same name, the reference number may vary depending on the drawing, and the reference number is only described for convenience of explanation, and the concept, characteristic, function or effect of each component is not to be construed as limiting by the corresponding reference number.

In describing each figure, like reference numbers are used for like elements. Terms such as first and second may be used to describe various components, but the components should not be limited by the terms. These terms are only used for the purpose of distinguishing one component from another. For example, a first element may be termed a second element, and similarly, a second element may be termed a first element, without departing from the scope of the present disclosure. The term “and/or” includes any combination of a plurality of related listed items or any of a plurality of related listed items.

Unless defined otherwise, all terms used herein, including technical or scientific terms, have the same meaning as commonly understood by those skill in the art to which the present disclosure belongs.

Terms such as those defined in commonly used dictionaries should be interpreted as having meanings consistent with the meanings in the context of the related art, and unless explicitly defined herein, they should not be interpreted in ideal or excessively formal meanings.

Throughout the specification, when a part is said to be “connected” to another part, this includes not only the case of being “directly connected” but also the case of being “electrically connected” with another element in between. In addition, when a part is said to “include” a certain component, it means that it may further include other components, not excluding other components unless otherwise stated, and it should be understood that the presence or addition of features, numbers, steps, operations, components, parts, or combinations thereof is not excluded in advance.

As used herein, ‘unit’ or ‘module’ may include a unit realized by hardware or software, or a unit realized by using both, and one unit may be realized by using two or more hardware may be, or two or more units may be realized by one hardware.

Artificial intelligence (AI) refers to the field of researching artificial intelligence or methodology to create it, and machine learning refers to the field of defining various problems dealt with in the field of artificial intelligence and researching a methodology for solving them. Machine learning is also defined as an algorithm that improves the performance of a certain task through constant experience.

An artificial neural network (ANN) which is a model used in machine learning may refer to an overall model that has problem-solving capabilities and may be composed of artificial neurons (nodes) that form a network by synaptic coupling. Such an artificial neural network may be defined by a connection pattern between neurons in different layers, a learning process that updates learning parameters in the model, and an activation function that generates output values.

An artificial neural network may include an input layer, an output layer, and optionally one or more hidden layers. Each layer may include one or more neurons, and the artificial neural network may include neurons and synapses connecting the neurons. In an artificial neural network, each neuron may output a function value of an activation function for input signals input through a synapse, a weight of each layer, and a bias.

Learning parameters of the model refer to parameters determined through learning and includes weights of synaptic connections and biases of neurons. Hyperparameters refer to parameters that should be set before learning in a machine learning algorithm, and may include a learning rate, number of iterations, a mini-batch size, an initialization function, and the like.

The purpose of learning of the artificial neural network may be understood as determining learning parameters that minimize a loss function. The loss function may be used as an index for determining an optimal learning parameter in a learning process of the artificial neural network. Machine learning may be classified into, for example, supervised learning, unsupervised learning, and reinforcement learning according to the learning method.

Among artificial neural networks, machine learning implemented by a deep neural network (DNN) including a plurality of hidden layers is also called deep learning, and deep learning is a part of machine learning. Hereinafter, machine learning is used to include deep learning. Artificial intelligence may be performed by an artificial neural network module.

Hereinafter, a fault detection method for a solenoid actuator according to the present disclosure will be described in detail with reference to the accompanying drawings.

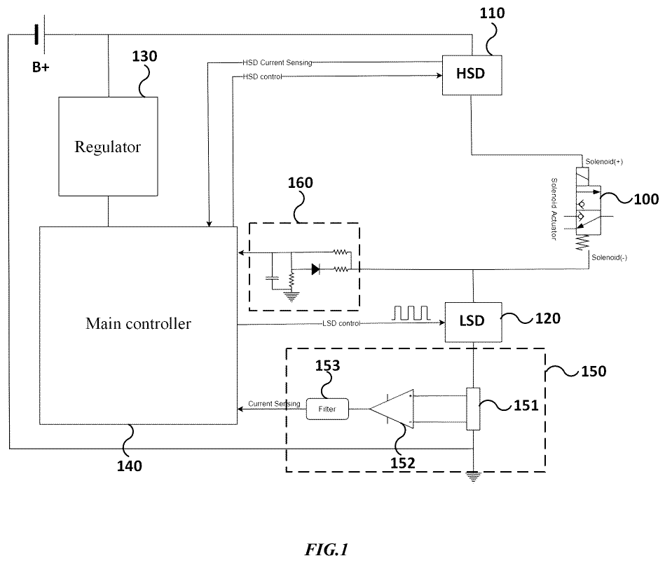

FIG. 1 is a drive circuit diagram of a general solenoid actuator 100.

A battery voltage (B+) may be connected to a (+) terminal of the solenoid actuator 100 through a high-side driver (HSD) 110, and a ground (GND) may be connected to a (−) terminal of the solenoid actuator 100 through a low-side driver (LSD) 120. The battery voltage (B+) may be converted in a regulator 130, and a drive voltage may be applied to a main controller 140. The main controller 140 may detect a current value flowing through the (+) terminal of the solenoid actuator 100 through the high-side driver 110. A current sensing unit 150 may be connected between the low-side driver 120 and the ground such that a current detection value flowing to the (−) terminal of the solenoid actuator 110 may be detected by the current sensing unit 150 and a current detection value may be sent to the main controller 140.

The main controller 140 may drive the solenoid actuator 100 by outputting signals to the high-side driver 110 and the low-side driver 120 based on the current detection value provided from the current sensing unit 150. Each of the high-side driver 110 and the low-side driver 120 may include a switching element whose on/off may be controlled by the main controller 140.

The current sensing unit 150 may include a shunt resistor 151, an amplifier 152, and a filter 153. The shunt resistor 151 is connected between the low-side driver 120 and the ground, and a voltage drop occurs in the shunt resistor 151 according to a current flowing through the solenoid actuator. The amplifier 152 amplifies a voltage across opposite ends of the shunt resistor 151, and the filter 153 filters the voltage amplified by the amplifier 152 and provides a current detection value to the main controller 140. The amplifier 152 may include an operational amplifier 502, and the filter 53 may include a low pass filter including a resistor R and a capacitor. The current sensing unit 150 may be connected between the (−) terminal of the solenoid actuator and the low-side driver 120.

The solenoid actuator 100 may have open (e.g., open circuit, disconnection, etc.) faults and short (e.g., short circuit) faults. In the case of an open fault, it may mean phenomenon in which a wire harness of the solenoid actuator 100 is not connected well due to collision, vibration, and the like during operation of the solenoid actuator 100, a disconnection occurs in a drive circuit due to damage to a coil itself, or a resistance of the solenoid increases.

In the case of a short fault, it may occur because of a miscontact between different wire harnesses due to collision, vibration, and other factors during operation of the solenoid actuator 100 or because of factors such as excessive current and high temperature. When a short fault occurs, an inductance and an impedance of the coil of the solenoid actuator 100 are very small and a current rise rate is significantly fast, and thus, if not limited, it may reach tens of amperes for several microseconds, resulting in damage to the solenoid actuator drive system.

Accordingly, means for detecting open and short faults of the solenoid actuator 100 are required. Fault diagnosis for the solenoid actuator 100 is performed in the main controller 140. The main controller 140 may detect an open fault based on an HSD current measurement value obtained by measuring a current of the high-side driver 110 and the current detection value of the current sensing unit 150 while the solenoid actuator 100 is driven. Here, the term “while the solenoid actuator 100 is driven” means while current is controlled in the solenoid actuator 100 by turning on both the high-side driver 110 and the low-side driver 120.

In addition, a short monitoring unit 160 may be connected between the (−) terminal of the solenoid actuator 100 and the low-side driver 120, and the short monitoring unit 160 may detect a voltage value applied to the (−) terminal of the solenoid actuator 100 as a short monitoring measurement value and provide the short monitoring measurement value to the main controller 140. The main controller 140 may detect a short fault based on the short monitoring measurement value applied to the solenoid actuator 100.

As described above, since the open and short fault of the conventional solenoid actuator 100 occurs while the solenoid actuator 100 is being driven, when the driving of the solenoid actuator is stopped due to various reasons (e.g., power consumption minimization of the solenoid actuator, drive noise minimization, etc.), the solenoid actuator fault may not be diagnosed.

Particularly, if a fault occurs during a non-drive period of the solenoid, such as when the solenoid actuator has been stopped for a long time or an impact is applied to the solenoid actuator while it is stopped, it may not be determined whether a fault occurs or not until the solenoid actuator is driven. Accordingly, there is a risk of damaging the solenoid actuator drive system by applying a current to the solenoid actuator that is out of order.

The fault detection method for a solenoid actuator according to the present disclosure may be implemented based on the drive circuit of the solenoid actuator of FIG. 1, and the fault detection method for a solenoid actuator according to the present disclosure may be executed in the main controller 140 of FIG. 1. The main controller 140 of the present disclosure may diagnose whether a fault of the solenoid actuator occurs or not in a state where a current of the solenoid actuator is not controlled.

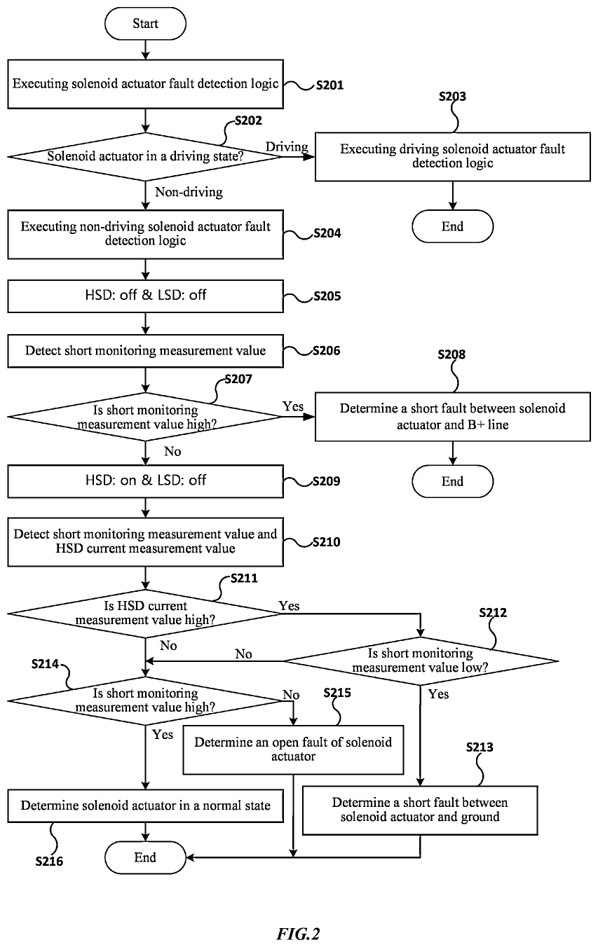

FIG. 2 is a flowchart illustrating a fault detection method for a solenoid actuator according to the present disclosure.

It is preferable that an HSD current threshold value and a short monitoring threshold value of a normal solenoid actuator (e.g., a solenoid actuator in a normal state) are stored in advance in the main controller 140 to diagnose a fault of the solenoid actuator 100 that is in a non-driving state. Each of the HSD current threshold value and the short monitoring threshold value may include both upper and lower limits, or only one of the upper and lower limits.

The main controller 140 executes a fault detection logic of the solenoid actuator 100 (S201). The main controller 140 may execute the fault detection logic of the solenoid actuator 100 according to a self-set cycle (e.g., 10 msec, 100 msec, etc.) or may execute it by receiving instructions from a higher level controller. As another embodiment, the main controller 140 may execute the fault detection logic when a fault symptom of the solenoid actuator 100 is detected. As another embodiment, the fault detection logic execution cycle of the solenoid actuator 100 may be adjusted based on a drive period, a production date and the like of the solenoid actuator 100. As another embodiment, the higher level controller may instruct the main controller 140 to execute the fault detection logic of the solenoid actuator 100 according to a user's request. As another embodiment, the main controller 140 may execute the fault detection logic in a non-driving state before driving the solenoid actuator 100 and then may allow the solenoid actuator 100 to be driven when a normal state is detected.

The main controller 140 determines whether the solenoid actuator 100 is in a driving state (S202). When both the high-side driver 110 and the low-side driver 120 of the solenoid actuator 100 are in an active on state, it is determined that the solenoid actuator 100 is in a driving state, and when at least one of the high-side driver 110 and the low-side driver 120 of the solenoid actuator 100 is not in the active on state, it is determined that the solenoid actuator 100 is in a non-driving state.

The main controller 140 executes a driving solenoid actuator fault detection logic when the solenoid actuator 100 is in a driving state (S203). The driving solenoid actuator fault detection logic may include a logic for detecting an open fault based on the HSD current measurement value obtained by measuring the current of the high-side driver 110 and the current detection value of the current sensing unit 150, and a logic for detecting a short fault by detecting, by the short monitoring unit 160, a short monitoring measurement value applied to the (−) terminal of the solenoid actuator 100.

The main controller 140 executes a non-driving solenoid actuator fault detection logic when the solenoid actuator 100 is in a non-driving state (S204). Since there is no current flowing through the solenoid actuator when the solenoid actuator is in a non-driving state, the driving solenoid actuator fault detection logic for detecting a fault based on the current detection value of the current sensing unit 150 may not be applied. In the present disclosure, a novel logic for detecting a fault of the non-driving solenoid actuator is proposed.

First, the main controller 140 detects a short monitoring measurement value in a state where both the high-side driver and the low-side driver are turned off (S205, S206). The short monitoring measurement value may be obtained through the short monitoring unit 160.

The main controller 140 compares the short monitoring measurement value with the pre-stored short monitoring threshold value, and when the short monitoring measurement value is higher than the short monitoring threshold value (S207), it is determined that there is a short fault between the solenoid actuator and the B+ line (S208). That is, in a state where both the high-side driver (HSD) 110 and the low-side driver (LSD) 120 are turned off, it is a normal state when the short monitoring measurement value of the short monitoring unit 160 is close to 0. However, when the solenoid actuator 100 and the B+ line are shorted, the short monitoring measurement value of the short monitoring unit 160 increases close to the B+ voltage. Accordingly, in step S208, in a state where both the high-side driver (HSD) 110 and the low-side driver (LSD) 120 are turned off and no current flows through the solenoid actuator 100, a short fault between the solenoid actuator 100 and the B+ line may be detected.

In another embodiment, in a non-driving state of the solenoid actuator, when the short fault between the solenoid actuator and the B+ line is detected, the main controller may prevent the solenoid actuator from being driven. If current flows through the solenoid actuator in a state where the solenoid actuator and the B+ line are shorted, it may have a fatal adverse effect on the service life of the solenoid actuator and other parts. For this reason, when it is determined that the solenoid actuator and the B+ line are shorted, the main controller may stop driving of the solenoid actuator and send an alarm to a higher level controller or a user.

When the short monitoring measurement value is not higher than the short monitoring threshold value in step S207, that is, if a short fault between the solenoid actuator 100 and the B+ line is not detected (S207), the main controller 140 may allow the low-side driver (LSD) 120 to maintain an off state and the high-side driver (HSD) 110 to be in an on state (S209).

In a state where the high-side driver (HSD) 110 is turned on and the low-side driver (LSD) 120 is turned off, the main controller 140 detects the short monitoring measurement value and the HSD current measurement value (S210). In such a case, since the low-side driver (LSD) 120 is in an off state, while the high-side driver (HSD) 110 is in an on state, the solenoid actuator 100 may maintain a non-driving state where current does not flow. That is, if the solenoid actuator 100 is in a normal state, even if the high-side driver (HSD) 110 is turned on, the HSD current of the high-side driver (HSD) 110 should not flow, and because the high-side driver (HSD) 110 is turned on and conducts, the short monitoring measurement value of the short monitoring unit 160 should be in a state equal to or higher than the short monitoring threshold value.

However, when the solenoid actuator 100 and the ground (GND) line are shorted, a closed-loop circuit is formed in the high-side driver (HSD), the B+ line, and the ground (GND) line, such that the HSD current flows, and a potential of the short monitoring unit 160 becomes a ground (GND) potential, causing the short monitoring measurement value to fall below the short-monitoring threshold value.

The main controller 140 determines whether the HSD current measurement value is higher than the HSD current threshold value (S211). When the HSD current measurement value is higher than the HSD current threshold value, it is determined whether the short monitoring measurement value is lower than the short monitoring threshold value (S212). When the short monitoring measurement value is lower than the short monitoring threshold value, it is determined that there is a short fault between the solenoid actuator and the ground (GND) (S213). In step S212, when the HSD current measurement value is higher than the HSD current threshold value but the short monitoring measurement value is not lower than the short monitoring threshold value, it is determined that there is no short fault between the solenoid actuator and ground (GND), and the process proceeds to step S214.

Meanwhile, when the high-side driver (HSD) 110 is turned on in a state where the solenoid actuator is open (e.g., disconnected), no current flows through the high-side driver (HSD) 110, and no voltage is applied to the short monitoring unit 160, and accordingly, the short monitoring measurement value becomes lower than the short monitoring threshold value.

When the HSD current measurement value is not higher than the HSD current threshold value in step S211, the main controller 140 determines whether the short monitoring measurement value is higher than the short monitoring threshold value (S214). When the short monitoring measurement value is not higher than the short monitoring threshold value in step S214, it is determined that the solenoid actuator has an open fault (S215).

On the other hand, when the short monitoring measurement value is higher than the short monitoring threshold value in step S214, it is determined that the solenoid actuator is in a normal state (S216).

As described above, according to the present disclosure, a short fault between the solenoid actuator 110 and the B+ line may be detected based on the short monitoring measurement value in a state where both the high-side driver (HSD) 110 and the low-side driver (LSD) 120 are turned off. In addition, in a state where the high-side driver (HSD) 110 is turned on and the low-side driver (LSD) 120 is turned off, a short fault between the solenoid actuator and the ground (GND) line and an open fault of the solenoid actuator may be detected based on the short monitoring measurement value and the HSD current measurement value.

The fault detection logic for the solenoid actuator is designed to diagnose only the short or open of the solenoid actuator, but the diagnosis is not made for the characteristic change according to the endurance progression of the solenoid actuator. That is, since the fault is determined by comparing various measurement values and corresponding threshold values in a state where the solenoid actuator is driven or not driven, the detection may be possible only after the final open or short of the solenoid actuator occurs. Accordingly, it may exceed a normal replacement timing and the entire body needs to be replaced, which may adversely affect the service life of other parts. Therefore, there is a need for a system for diagnosing fault symptoms of the solenoid actuator and giving an alarm to the user before a fault of the solenoid actuator occurs.

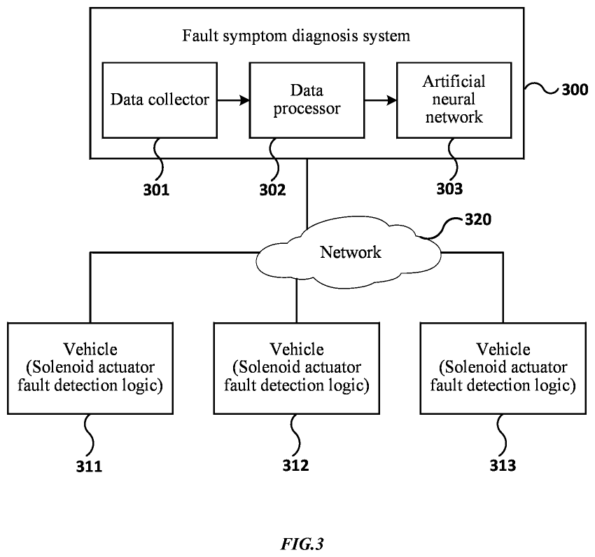

FIG. 3 is a configuration diagram illustrating a fault symptom diagnosis system for a solenoid actuator according to the present disclosure. The fault symptom diagnosis system 300 for the solenoid actuator according to the present disclosure may be implemented with a server.

A plurality of vehicles 311, 312, and 313 may be connected to the fault symptom diagnosis system 300 through a network 320. As another embodiment, each of the vehicles 311, 312, and 313 may be directly connected to the fault symptom diagnosis system 300, or only data collected from each vehicle may be input to the fault symptom diagnosis system 300.

The solenoid actuator fault detection logic is executed for each vehicle, and the short monitoring measurement value, the HSD current measurement value, and the current detection value may be cumulatively stored (e.g., accumulated). That is, for each vehicle, fault detection measurement values during the entire life cycle from when the solenoid actuator is in a normal state, through a period in time when the solenoid actuator gradually deteriorates as the usage period increases until the fault symptom appears, and to the final fault may be accumulated and collected.

The fault symptom diagnosis system 300 includes a data collector 301 configured to collect data including fault detection measurement values for each of a plurality of diagnosis dates, a fault date, and a fault type from a plurality of vehicles, a data processor 302 configured to calculate a remaining service life for each diagnosis date based on the collected data, and an artificial neural network 303 configured to learn to predict a fault type and a remaining service life based on the fault detection measurement value.

The data collector 301 acquires solenoid actuator fault diagnosis data collected from the plurality of vehicles. The fault diagnosis data may include fault detection measurement values for each diagnosis date, a fault date, and a fault type. The fault detection measurement values may include a short monitoring measurement value, an HSD current measurement value, and a current detection value. The fault detection measurement value may further include a B+ voltage, a PWM control signal, a target current value, and the like. The acquired fault diagnosis data may be used as learning data for the artificial neural network 303. Since it may be excessive to store all the fault detection measurement values for each diagnosis date and use them as learning data, only some of the diagnosis dates may be selected and only fault detection measurement values of the selected diagnosis date may be used as learning data. The fault type may include a short fault between the solenoid actuator and the B+ line, a short fault between the solenoid actuator and the ground (GND), and an open fault of the solenoid actuator.

The data processor 302 calculates the remaining service life on the diagnosis date based on a difference between a fault date and the diagnosis date. Based on this, the fault detection measurement value, the remaining service life, and the fault type data for each diagnosis date may be secured. The data processor 302 may provide the fault detection measurement value, the remaining service life and the fault type data to the artificial neural network 303 as learning data.

The artificial neural network 303 learns to classify the remaining service life and a fault type class from the fault detection measurement values using the learning data provided from the data processor 302. The artificial neural network 303 may set a difference between a predicted remaining service life and an actual remaining service life as a remaining service life loss function and may learn such that the remaining service life loss function converges to 0. As another embodiment, the artificial neural network 303 may set a difference between a predicted fault type class and an actual fault type class as a fault type loss function and may learn such that the fault type loss function converges to 0. As another embodiment, learning may be performed in consideration of both the remaining service life loss function and the fault type loss function.

The fault symptom diagnosis system may diagnose a fault symptom of the solenoid actuator by using the artificial neural network learned based on the plurality of learning data. The learned artificial neural network may predict the fault type and the remaining service life when test fault detection measurement values are input, and when the predicted remaining service life is within a predetermined range (e.g., within 6 months), it may diagnose that a fault symptom appears in the corresponding predicted fault type class.

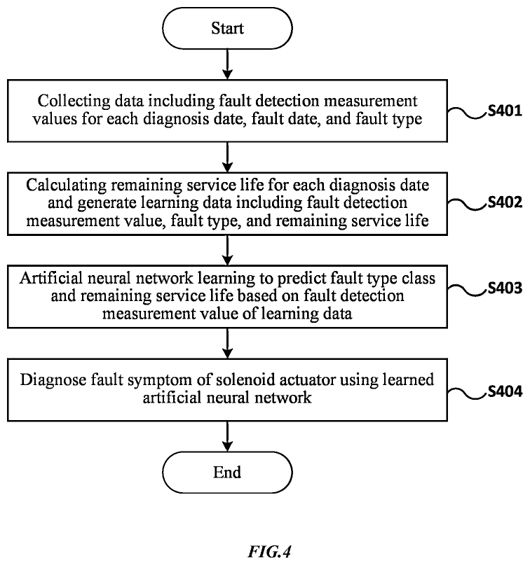

FIG. 4 is a flowchart illustrating a fault symptom diagnosis method for a solenoid actuator according to an embodiment of the present disclosure.

The fault symptom diagnosis system collects data including fault detection measurement values for each diagnosis date, a fault date, and a fault type from a plurality of vehicles (S401).

The fault symptom diagnosis system calculates a remaining service life for each diagnosis date using a diagnosis date and a fault date and generates learning data including the fault detection measurement value, the fault type, and the remaining service life (S402).

The fault symptom diagnosis system allows the artificial neural network to learn to predict a fault type class and a remaining service life based on the fault detection measurement value of the learning data (S403).

When test fault detection measurement values are input, the fault symptom diagnosis system diagnoses a fault symptom of the solenoid actuator using the learned artificial neural network (S404).

The above description of the present disclosure is for illustrative purposes, and those skilled in the art may understand that it may be easily modified into other specific forms without changing the technical spirit or essential features of the present disclosure. Accordingly, the embodiments described above should be understood as illustrative in all respects and not limiting. For example, each component described as a single type may be implemented in a distributed manner, and similarly, components described as distributed may be implemented in a combined form.

The scope of the present disclosure is indicated by the following claims rather than the detailed description above, and all changes or modifications derived from the meaning and scope of the claims and equivalent concepts should be construed as being included in the scope of the present disclosure.

What is claimed is:

1. A fault detection method for a solenoid actuator in a drive circuit of the solenoid actuator comprising a main controller, a high-side driver, a low-side driver and a short monitoring unit, the method comprising:
detecting, by the main controller, a first short monitoring measurement value of the short monitoring unit in a state where at least one of the high-side driver and the low-side driver is turned off;
comparing, by the main controller, the first short monitoring measurement value with a pre-stored short monitoring threshold value; and
determining, by the main controller, a fault of the solenoid actuator based on the comparison result.

2. The method of claim 1, wherein the determining, by the main controller, a fault of the solenoid actuator based on the comparison result comprises determining that there is a short fault between the solenoid actuator and a B+ line when the first short monitoring measurement value is higher than the short monitoring threshold value in a state where both the high-side driver and the low-side driver are turned off.

3. The method of claim 2, further comprising:
preventing, by the main controller, the solenoid actuator from being driven when it is determined that there is a short fault between the solenoid actuator and the B+ line.

4. The method of claim 1, further comprising:
detecting, by the main controller, a second short monitoring measurement value of the short monitoring unit and a second HSD current measurement value of the high-side driver in a state where the high-side driver is turned on and the low-side driver is turned off; and
comparing, by the main controller, the second short monitoring measurement value with a pre-stored short monitoring threshold value and comparing, by the main controller, the second HSD current measurement value with a pre-stored HSD current threshold value.

5. The method of claim 4, wherein the determining, by the main controller, a fault of the solenoid actuator based on the comparison result comprises determining that there is a short fault between the solenoid actuator and a ground (GND) when the second HSD current measurement value is higher than the HSD current threshold value and the short monitoring measurement value is lower than the short monitoring threshold value.

6. The method of claim 4, wherein the determining, by the main controller, a fault of the solenoid actuator based on the comparison result comprises determining that there is an open fault of the solenoid actuator when the second HSD current measurement value is not higher than the HSD current threshold value and the short monitoring measurement value is not higher than the short monitoring threshold value.

7. The method of claim 4, wherein the determining, by the main controller, a fault of the solenoid actuator based on the comparison result comprises determining that the solenoid actuator is normal when the second HSD current measurement value is not higher than the HSD current threshold value and the short monitoring measurement value is higher than the short monitoring threshold value.

8. The method of claim 1, further comprising:
executing, by the main controller, a driving solenoid actuator fault detection logic in a state where both the high-side driver and the low-side driver are turned on.

9. A fault symptom diagnosis system for a solenoid actuator, the system comprising:
a data collector configured to collect data including a fault detection measurement value for each of a plurality of diagnosis dates, a fault date, and a fault type;
a data processor configured to calculate a remaining service life for each of a plurality of diagnosis dates based on the collected data and generate learning data including the fault detection measurement value, the remaining service life, and the fault type; and
an artificial neural network configured to learn to predict a fault type class and a remaining service life based on the fault detection measurement value of the learning data,
wherein a fault symptom of the solenoid actuator is diagnosed using the artificial neural network.

10. The system of claim 9, wherein the fault detection measurement value includes a short monitoring measurement value, an HSD current measurement value, and a current detection value.

11. The system of claim 10, wherein the fault detection measurement value further includes at least one of a B+ voltage, a PWM control signal, and a target current value.

12. The system of claim 9, wherein the fault type includes a short fault between the solenoid actuator and a B+ line, a short fault between the solenoid actuator and a ground (GND), and an open fault of the solenoid actuator.

13. The system of claim 9, wherein the artificial neural network sets a difference between a predicted remaining service life and an actual remaining service life as a remaining service life loss function and learns such that that the remaining service life loss function converges to 0.

14. The system of claim 9, wherein the artificial neural network sets a difference between a predicted fault type class and an actual fault type class as a fault type loss function and learns such that that the fault type loss function converges to 0.

15. A fault symptom diagnosis method for a solenoid actuator, the method comprising:
collecting, by a fault symptom diagnosis system, data including a fault detection measurement value for each of a plurality of diagnosis dates, a fault date, and a fault type;
calculating, by the fault symptom diagnosis system, a remaining service life for each of a plurality of diagnosis dates based on the collected data and generating learning data including the fault detection measurement value, the remaining service life, and the fault type;
learning by an artificial neural network such that the fault symptom diagnosis system predicts a fault type class and a remaining service life based on the fault detection measurement value of the learning data; and
diagnosing a fault symptom of the solenoid actuator using the learned artificial neural network.

16. The method of claim 15, wherein the fault detection measurement value includes a short monitoring measurement value, an HSD current measurement value, and a current detection value.

17. The method of claim 16, wherein the fault detection measurement value further includes at least one of a B+ voltage, a PWM control signal, and a target current value.

18. The method of claim 15, wherein the fault type includes a short fault between the solenoid actuator and a B+ line, a short fault between the solenoid actuator and a ground (GND), and an open fault of the solenoid actuator.

19. The method of claim 15, wherein the artificial neural network sets a difference between a predicted remaining service life and an actual remaining service life as a remaining service life loss function and learns such that that the remaining service life loss function converges to 0.

20. The method of claim 15, wherein the artificial neural network sets a difference between a predicted fault type class and an actual fault type class as a fault type loss function and learns such that that the fault type loss function converges to 0.
